(19) United States
(12) Patent Application Publication
(10) Pub. No.: US 2021/0336196 A1
(43) Pub. Date: Oct. 28, 2021

(54) ORGANIC LIGHT-EMITTING DIODE DISPLAY AND MANUFACTURING METHOD THEREOF

(71) Applicant: WUHAN CHINA STAR OPTOELECTRONICS TECHNOLOGY CO., LTD., Wuhan (CN)

(72) Inventors: Yuejun Tang, Wuhan (CN); Xueyun Li, Wuhan (CN)

(21) Appl. No.: 16/320,045

(22) PCT Filed: Dec. 27, 2018
(86) PCT No.: PCT/CN2018/124430

§ 371 Date: Jan. 23, 2019

(30) Foreign Application Priority Data
Oct. 31, 2018 (CN) 201811284311.X

(51) Int. Cl. H01L 51/52; H01L 51/56

(52) U.S. Cl. CPC H01L 51/5253; H01L 51/5275; H01L 51/56; H01L 51/5281

(57) ABSTRACT

An organic light-emitting diode display and a manufacturing method thereof are provided. A protective cover is arranged to encapsulate an organic light-emitting diode array substrate by spreading a sealant around the periphery of the organic light-emitting diode array substrate and bonding the protective cover with the sealant. Compared with existing technologies, the cover encapsulation and thin film encapsulation are omitted, which has the advantage of simplifying working process. Meanwhile, the organic light-emitting diode display has the advantages of a thin thickness and a narrow frame.

### FIELD OF INVENTION

The present disclosure relates to the field of display technologies, and more particularly to an organic light-emitting diode display and a manufacturing method thereof.

### BACKGROUND OF INVENTION

Nowadays, Organic Light Emitting Diode (OLED) display, which is used as display device for displaying images, has been paid much attention. Unlike Liquid Crystal Display (LCD), OLED display is self-emissive and does not need a separate light source, whereby it can be manufactured into a thinner and lighter display device, and more easily achieve the characteristic of flexible foldable display. In addition, OLED display also has superior characteristics such as low power consumption, high luminance and high response speeds. With the development of OLED displays, the trend of OLED displays is to be lighter and thinner and have narrow frame; thus, how to reduce the thickness and the frame width of the OLED displays is an important research direction.

### SUMMARY OF INVENTION

The embodiment of the present disclosure provides an organic light-emitting diode display and a manufacturing method thereof, the organic light-emitting diode display has the advantages of a thin thickness and a narrow frame.

An organic light-emitting diode display includes an organic light-emitting diode array substrate; a protective cover, the protective cover and the organic light-emitting diode array substrate are correspondingly arranged, and the protective cover is used to encapsulate the organic light-emitting diode array substrate; and a sealant frame, the sealant frame surrounds a periphery of the organic light-emitting diode array substrate and bonds with the protective cover.

In an embodiment of the present disclosure, the organic light-emitting diode display further includes a transmission enhanced layer positioned between the organic light-emitting diode array substrate and the protective cover.

In an embodiment of the present disclosure, the transmission enhanced layer includes at least two transmission enhanced layers having different refractive indexes, and a refractive index of a cathode of the organic light-emitting diode array substrate, the refractive indexes of the at least two transmission enhanced layer and a refractive index of the protective cover gradually increase or decrease in the direction from the organic light-emitting diode array substrate to the protective cover.

In an embodiment of the present disclosure, the organic light-emitting diode display further includes an anti-reflection layer.

In an embodiment of the present disclosure, the anti-reflection layer is positioned between the organic light-emitting diode array substrate and the protective cover.

In an embodiment of the present disclosure, the organic light-emitting diode display further includes a transmission enhanced layer. The transmission enhanced layer includes a first transmission enhanced layer and a second transmission enhanced layer. The first transmission enhanced layer is positioned between the organic light-emitting diode array substrate and the anti-reflection layer. The second transmission enhanced layer is positioned between the anti-reflection layer and the protective cover. A refractive index of the first transmission enhanced layer falls in between a refractive index of a cathode of the organic light-emitting diode array substrate and a refractive index of the anti-reflection layer. A refractive index of the second transmission enhanced layer falls in between a refractive index of the anti-reflection layer and a refractive index of the protective cover.

In an embodiment of the present disclosure, the anti-reflection layer is provided on an outer side of the protective cover. The outer side of the protective cover is far away from the organic light-emitting diode array substrate.

In an embodiment of the present disclosure, the anti-reflection layer is a circular polarizer.

In an embodiment of the present disclosure, the organic light-emitting diode display further includes a barrier layer positioned between the organic light-emitting diode array substrate and the protective layer.

In an embodiment of the present disclosure, the barrier layer is an inorganic layer, or a laminated layer including multiple inorganic layers and multiple organic layers alternately stacked on the organic light-emitting diode array substrate.

A method of manufacturing an organic light-emitting diode display includes preparing an organic light-emitting diode array substrate, a protective cover and a sealant; attaching the protective cover on the organic light-emitting diode array substrate; and spreading the sealant around a periphery of the organic light-emitting diode array substrate and bonding the protective cover with the sealant.

In an embodiment of the present disclosure, the method further includes forming a transmission enhanced layer between the organic light-emitting diode array substrate and the protective layer.

In an embodiment of the present disclosure, the transmission enhanced layer includes at least two transmission enhanced layers having different refractive indexes. A refractive index of a cathode of the organic light-emitting diode array substrate, the refractive indexes of the at least two transmission enhanced layers and a refractive index of the protective cover gradually increase or decrease in the direction from the organic light-emitting diode array substrate to the protective cover.

In an embodiment of the present disclosure, the method further includes attaching an anti-reflection layer.

In an embodiment of the present disclosure, the step of attaching an anti-reflection layer includes attaching an anti-reflection layer between the organic light-emitting diode array substrate and the protective cover.

In an embodiment of the present disclosure, the method further includes forming a first transmission enhanced layer positioned between the organic light-emitting diode array substrate and the anti-reflection layer, and forming a second transmission enhanced layer between the anti-reflection layer and the protective cover. A refractive index of the first transmission enhanced layer falls in between a refractive index of a cathode of the organic light-emitting diode array substrate and a refractive index of the anti-reflection layer, and a refractive index of the second transmission enhanced layer falls in between the refractive index of the anti-reflection layer and a refractive index of the protective cover.

In an embodiment of the present disclosure, the step of attaching an anti-reflection layer includes attaching an anti-reflection layer on an outer side of the protective cover, and the outer side of the protective cover is far away from the organic light-emitting diode array substrate.

In an embodiment of the present disclosure, the anti-reflection layer is a circular polarizer.

In an embodiment of the present disclosure, the method further includes forming a barrier layer between the organic light-emitting diode array substrate and the protective cover.

In an embodiment of the present disclosure, the barrier layer is an inorganic layer, or a laminated layer including multiple layers and multiple organic layers alternately stacked on the organic light-emitting diode array substrate.

The embodiment of the present disclosure arranges the protective cover to encapsulate the organic light-emitting diode array substrate by spreading the sealant around the periphery of the organic light-emitting diode array substrate and bonding the protective cover with the sealant. Compared with existing technologies, the present disclosure abandons cover encapsulation and thin film encapsulation, which has the advantage of simplifying working process. Meanwhile, the organic light-emitting diode display has the advantages of a thin thickness and a narrow frame.

### DESCRIPTION OF DRAWINGS

FIG. 1 is a top view of an OLED display according to a first exemplary embodiment.

FIG. 2 is a cross-sectional view taken along line A-A of FIG. 1 according to a first exemplary embodiment.

FIG. 3 is a cross-sectional view taken along line A-A of FIG. 1 according to a second exemplary embodiment.

FIG. 4 is a cross-sectional view taken along line A-A of FIG. 1 according to a third exemplary embodiment.

FIG. 5 is a cross-sectional view taken along line A-A of FIG. 1 according to a fourth exemplary embodiment.

FIG. 6 is a cross-sectional view taken along line A-A of FIG. 1 according to a fifth exemplary embodiment.

FIG. 7 is a cross-sectional view taken along line A-A of FIG. 1 according to a sixth exemplary embodiment.

FIG. 8 is a cross-sectional view taken along line A-A of FIG. 1 according to a seventh exemplary embodiment.

FIG. 9 is a flow chart illustrating a method of manufacturing the organic light-emitting diode display according to the first embodiment.

### DETAILED DESCRIPTION OF PREFERRED EMBODIMENTS

Hereinafter, the embodiments of the present disclosure are clearly and completely described in conjunction with the attached drawings. Obviously, the embodiments described below are only partial embodiments of the present disclosure but not all of them. Based on the embodiments described in the present disclosure, all other embodiments acquired by a person having ordinary skill in the art without creative work fall within the scope of the protection of the present disclosure.

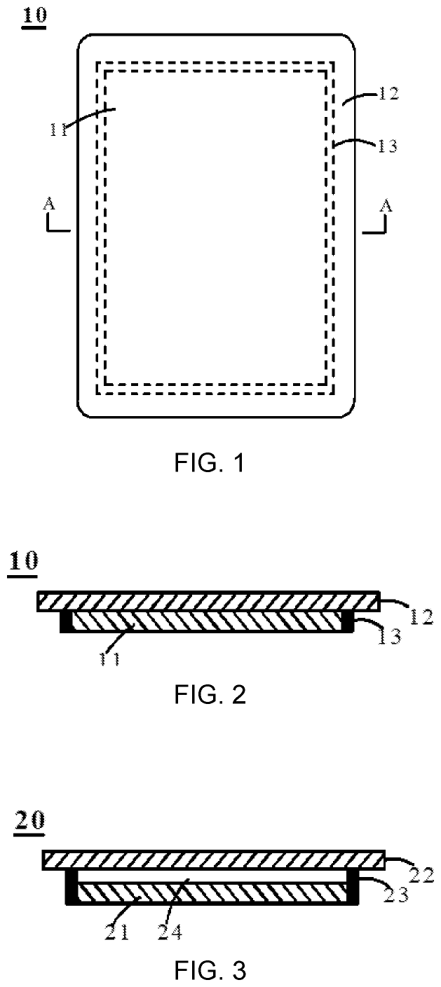

Referring to FIG. 1 and FIG. 2, FIG. 1 and FIG. 2 are schematic structural diagrams showing an OLED display 10 according to a first exemplary embodiment. The OLED display 10 includes an organic light-emitting diode array substrate 11, a protective cover 12, wherein the protective cover 12 and the organic light-emitting diode array substrate 11 are correspondingly arranged, and the protective cover 12 is used to encapsulate the organic light-emitting diode array substrate 11, and a sealant frame 13, wherein the sealant frame 13 surrounds a periphery of the organic light-emitting diode array substrate 11 and bonds with the protective cover 12.

The organic light-emitting diode array substrate 11 includes a base body, an array of thin film transistors and an organic light-emitting diode layer that are sequentially stacked. Thereinto, the organic light-emitting diode layer includes but is not limited to an anode, an organic light-emitting layer and a cathode that are sequentially stacked. According to different structures of the organic light-emitting diode layer, the organic light-emitting diode layer is classified into a top-emitting type, a bottom-emitting type, a transmissive type or other types. In the first exemplary embodiment, the organic light-emitting diode layer is top-emitting type OLED; in other embodiments, the organic light-emitting diode layer can be bottom-emitting type OLED or transmissive type OLED.

The protective cover 12 is used to encapsulate the organic light-emitting diode array substrate 11, which protects the cathode and the organic light-emitting layer of the organic light-emitting diode array substrate 11 from contacting with oxygen and water vapor which can shorten the lifespan of the OLED display 10.

The sealant frame 13 is utilized to bind the protective cover 12 and the organic light-emitting diode array substrate 11 together and performs the sealing function. The forming method of the sealant frame 13 includes but is not limited to an application by a needle valve, a spray valve coating, etc. The material of the sealant frame 13 includes but is not limited to an ultraviolet-curing adhesive or a hot melt adhesive. The ultraviolet-curing adhesive includes but is not limited to epoxy resin ultraviolet-curing adhesive. The hot melt adhesive includes but is not limited to glass, vacuum sealing wax, etc.

Existing technologies encapsulate an organic light-emitting diode array substrate by cover encapsulation or thin film encapsulation, and then attaching a protective cover on a surface of the organic light-emitting diode array substrate after the encapsulation. The present disclosure directly uses the protective cover as the encapsulation layer of the organic light-emitting diode array substrate by spreading the sealant around the periphery of the organic light-emitting diode array substrate and bonding the protective cover with the sealant. Compared with existing technologies, the present disclosure abandons cover encapsulation and thin film encapsulation, which has the advantage of simplifying working process. Meanwhile, the organic light-emitting diode display has the advantages of a thin thickness and a narrow frame.

FIG. 3 is a cross-sectional view of an OLED display 20 according to a second exemplary embodiment. The OLED display 20 includes an organic light-emitting diode array substrate 21, a protective cover 22, wherein the protective cover 22 and the organic light-emitting diode array substrate 21 are correspondingly arranged, and the protective cover 22 is used to encapsulate the organic light-emitting diode array substrate 21, a sealant frame 23, wherein the sealant frame 23 surrounds a periphery of the organic light-emitting diode array substrate 21 and bonds with the protective cover 22, and a transmission enhanced layer 24 positioned between the organic light-emitting diode array substrate 21 and the protective cover 22.

The second exemplary embodiment is similar to the first exemplary embodiment. The difference between them is that a transmission enhanced layer 24 is positioned between the organic light-emitting diode array substrate 21 and the protective cover 22. The transmission enhanced layer 24 is used to weaken the phenomenon of total reflection of light emitted from the organic light-emitting diode array substrate in the process of propagation.

A refractive index of the transmission enhanced layer 24 falls in between refractive indexes of materials positioned at both sides of the transmission enhanced layer 24. The transmission enhanced layer 24 can be a single layer; a refractive index of the single layer falls in between a refractive index of a cathode of the organic light-emitting diode array substrate 21 and a refractive index of the protective cover 22. The transmission enhanced layer 24 can include at least two transmission enhanced layers having different refractive indexes and the refractive indexes of the at least two transmission enhanced layers gradually change so that the refractive index of the cathode of the organic light-emitting diode array substrate 21, the refractive indexes of the at least two transmission enhanced layers and the refractive index of the protective cover 22 gradually increase or decrease in the direction from the organic light-emitting diode array substrate 21 to the protective cover 22.

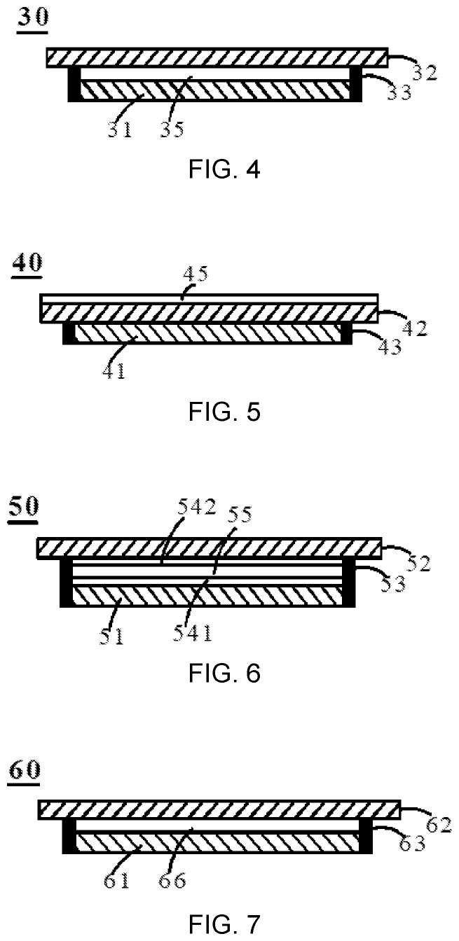

FIG. 4 is a cross-sectional view of an OLED display 30 according to a third exemplary embodiment. The OLED display 30 includes an organic light-emitting diode array substrate 31, a protective cover 32, wherein the protective cover 32 and the organic light-emitting diode array substrate 31 are correspondingly arranged, and the protective cover 32 is used to encapsulate the organic light-emitting diode array substrate 31, a sealant frame 33, wherein the sealant frame 33 surrounds a periphery of the organic light-emitting diode array substrate 31 and bonds with the protective cover 32, and an anti-reflection layer 35 positioned between the organic light-emitting diode array substrate 31 and the protective cover 32.

The third exemplary embodiment is similar to the first exemplary embodiment. The difference between them is that an anti-reflection layer 35 is positioned between the organic light-emitting diode array substrate 31 and the protective cover 32. The anti-reflection layer 35 is used to weaken the reflection of environment light so as to avoid impairing the display effect. The anti-reflection layer 35 is a circular polarizer.

FIG. 5 is a cross-sectional view of an OLED display 40 according to a fourth exemplary embodiment. The OLED display 40 includes an organic light-emitting diode array substrate 41, a protective cover 42, wherein the protective cover 42 and the organic light-emitting diode array substrate 41 are correspondingly arranged, and the protective cover 42 is used to encapsulate the organic light-emitting diode array substrate 41, a sealant frame 43, wherein the sealant frame 43 surrounds a periphery of the organic light-emitting diode array substrate 41 and bonds with the protective cover 42, and an anti-reflection layer 45 provided on an outer side of the protective cover 42, wherein the outer side of the protective cover 42 is far away from the organic light-emitting diode array substrate 41.

FIG. 6 is a cross-sectional view of an OLED display 50 according to a fifth exemplary embodiment. The OLED display 50 includes an organic light-emitting diode array substrate 51, a protective cover 52, wherein the protective cover 52 and the organic light-emitting diode array substrate 51 are correspondingly arranged, and the protective cover 52 is used to encapsulate the organic light-emitting diode array substrate 51, a sealant frame 53, wherein the sealant frame 53 surrounds a periphery of the organic light-emitting diode array substrate 51 and bonds with the protective cover 52, an anti-reflection layer 55 positioned between the organic light-emitting diode array substrate 51 and the protective cover 52, and a transmission enhanced layer 54 including a first transmission enhanced layer 541 and a second transmission enhanced layer 542. The first transmission enhanced layer 541 is positioned between the organic light-emitting diode array substrate 51 and the anti-reflection layer 55. The second transmission enhanced layer 542 is positioned between the anti-reflection layer 55 and the protective cover 52. A refractive index of the first transmission enhanced layer 541 falls in between a refractive index of a cathode of the organic light-emitting diode array substrate 51 and a refractive index of the anti-reflection layer 55. A refractive index of the second transmission enhanced layer 542 falls in between the refractive index of the anti-reflection layer 55 and a refractive index of the protective cover 52.

FIG. 7 is a cross-sectional view of an OLED display 60 according to a sixth exemplary embodiment. The OLED display 60 includes an organic light-emitting diode array substrate 61, a protective cover 62, wherein the protective cover 62 and the organic light-emitting diode array substrate 61 are correspondingly arranged, and the protective cover 62 is used to encapsulate the organic light-emitting diode array substrate 61, a sealant frame 63, wherein the sealant frame 63 surrounds a periphery of the organic light-emitting diode array substrate 61 and bonds with the protective cover 62, and a barrier layer 66 positioned between the organic light-emitting diode array substrate 61 and the protective cover 62.

The barrier layer 66 is arranged to stop an active cathode and an organic light-emitting layer of the organic light-emitting diode array substrate 61 from contacting with water vapor and oxygen.

Further, the barrier layer 66 is an inorganic layer, or a laminated layer including multiple inorganic layers and multiple organic layers alternately stacked on the organic light-emitting diode array substrate 61, which means that the laminated layer consists of an inorganic layer and an organic layer, or the laminated layer consists of multiple alternate layers including multiple inorganic layers and multiple organic layers. The inorganic layer is made of silicon nitride, silicon oxide, aluminum oxide, titanium oxide, magnesium oxide, etc. The organic layer is made of polyacrylate, etc.

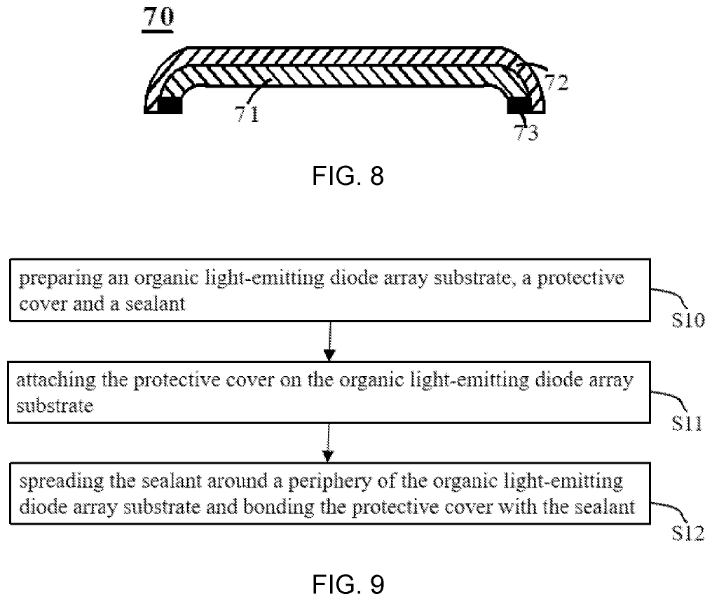

FIG. 8 is a cross-sectional view of an OLED display 70 according to a seventh exemplary embodiment, wherein two opposite sides of the OLED display 70 are curved surfaces. The OLED display 70 includes an organic light-emitting diode array substrate 71, a protective cover 72, wherein the protective cover 72 and the organic light-emitting diode array substrate 71 are correspondingly arranged, and the protective cover 72 is used to encapsulate the organic light-emitting diode array substrate 71, and a sealant frame 73, wherein the sealant frame 73 surrounds a periphery of the organic light-emitting diode array substrate 71 and bonds with the protective cover 72.

Two opposite sides of the OLED display 70 are curved surfaces, and the sealant positioned at two opposite sides of the protective cover 72 is positioned at opposite inner surfaces of the curved protective cover.

The second exemplary embodiment to the fifth exemplary embodiment described above further increase luminous efficiency or decrease reflectivity of environment light in order to improve display quality by arranging the transmission enhanced layer and the anti-reflection layer. The transmission enhanced layer, which is positioned between the organic light-emitting diode array substrate and the protective cover can be a single layer or multiple layers. The refractive index of each of the transmission enhanced layer falls in between refractive indexes of materials positioned at both sides of the transmission enhanced layer. The anti-reflection layer is a single layer. The anti-reflection layer can be positioned between the organic light-emitting diode array substrate and the protective cover. The anti-reflection layer can also be positioned on an outer side of the protective cover. The sixth exemplary embodiment further avoids the active cathode and the organic light-emitting layer from contacting with water vapor and oxygen by arranging the barrier layer. To be clear, the transmission enhanced layer, the anti-reflection layer and the barrier layer can be arbitrarily assembled according to demand, which is not limited to embodiments described above. The seventh exemplary embodiment illustrates a structure of an OLED display when opposite sides of the OLED display are curved surfaces.

Understandably, the present disclosure can arrange other functional layers on the basis of achieving a thin thickness and a narrow frame of OLED displays in order to improve overall performances of the OLED displays.

As shown in FIG. 9, FIG. 9 is a flow chart of a manufacturing method of OLED display 10 in the first exemplary embodiment; the manufacturing method includes steps below:

S10, preparing an organic light-emitting diode array substrate 11, a protective cover 12 and a sealant 13.

Specifically, the step is related to providing a base body and sequentially forming an array of thin film transistors and an organic light-emitting diode layer on the base body, then dividing the base body with the array of thin film transistors and the organic light-emitting diode layer to obtain multiple organic light-emitting diode array substrates 11 with required size.

S11, attaching the protective cover 12 on the organic light-emitting diode array substrate 11.

Specifically, the step is related to attaching the protective cover 12 on the side of the organic light-emitting diode array substrate 11 with an organic light-emitting layer.

S12, spreading the sealant 13 around a periphery of the organic light-emitting diode array substrate 11 and bonding the protective cover 12 with the sealant 13.

Specifically, the step is related to spreading the sealant 13 around a periphery of the organic light-emitting diode array substrate 11 after step S11 and bonding the protective cover 12 with the sealant 13. Note that the thickness of the sealant 13 at a chip bonding zone and corners of the organic light-emitting diode array substrates 11 is bigger than that of other zones so as to improve lifespan of the OLED display 10.

Further, the manufacturing method includes forming a transmission enhanced layer between the organic light-emitting diode array substrate 11 and the protective cover 12.

Further, the manufacturing method includes attaching an anti-reflection layer. The anti-reflection layer is attached by using an adhesive. The anti-reflection layer is a circular polarizer. The step of attaching an anti-reflection layer includes attaching an anti-reflection layer between the organic light-emitting diode array substrate 11 and the protective cover 12, or attaching an anti-reflection layer on an outer side of the protective cover 12, and the outer side of the protective cover 12 is far away from the organic light-emitting diode array substrate 11.

The manufacturing method of OLED displays of the present disclosure arranges the protective cover to encapsulate the organic light-emitting diode array substrate by spreading the sealant around the periphery of the organic light-emitting diode array substrate and bonding the protective cover with the sealant. Compared with existing technologies, the present disclosure abandons cover encapsulation and thin film encapsulation, which has the advantage of simplifying working process. Meanwhile, the organic light-emitting diode display has the advantages of a thin thickness and a narrow frame.

The illustration of above embodiments is only used to understand the scheme and the main idea of the present disclosure. It is understood by persons having ordinary skill in the art that they can modify embodiments described above or equally replace some technical features, but modifications and substitutions do not divert the nature of the corresponding technical solutions from the scope of the embodiments of the present disclosure.

1. An organic light-emitting diode display, comprising:
an organic light-emitting diode array substrate;
a protective cover, wherein the protective cover and the organic light-emitting diode array substrate are correspondingly arranged, and the protective cover is used to encapsulate the organic light-emitting diode array substrate; and
a sealant frame, wherein the sealant frame surrounds a periphery of the organic light-emitting diode array substrate and bonds with the protective cover.

2. The organic light-emitting diode display according to claim 1, wherein the organic light-emitting diode display further comprises a transmission enhanced layer positioned between the organic light-emitting diode array substrate and the protective cover.

3. The organic light-emitting diode display according to claim 2, wherein the transmission enhanced layer comprises at least two transmission enhanced layers having different refractive indexes, and a refractive index of a cathode of the organic light-emitting diode array substrate, the refractive indexes of the at least two transmission enhanced layers and a refractive index of the protective cover gradually increase or decrease in the direction from the organic light-emitting diode array substrate to the protective cover.

4. The organic light-emitting diode display according to claim 1, wherein the organic light-emitting diode display further comprises an anti-reflection layer.

5. The organic light-emitting diode display according to claim 4, wherein the anti-reflection layer is positioned between the organic light-emitting diode array substrate and the protective cover.

6. The organic light-emitting diode display according to claim 5, wherein the organic light-emitting diode display further comprises a transmission enhanced layer, and the transmission enhanced layer comprises a first transmission enhanced layer and a second transmission enhanced layer, wherein the first transmission enhanced layer is positioned between the organic light-emitting diode array substrate and the anti-reflection layer, and the second transmission enhanced layer is positioned between the anti-reflection layer and the protective cover, wherein a refractive index of the first transmission enhanced layer falls in between a refractive index of a cathode of the organic light-emitting diode array substrate and a refractive index of the anti-reflection layer, and a refractive index of the second transmission enhanced layer falls in between the refractive index of the anti-reflection layer and a refractive index of the protective cover.

7. The organic light-emitting diode display according to claim 4, wherein the anti-reflection layer is provided on an outer side of the protective cover, and the outer side of the protective cover is far away from the organic light-emitting diode array substrate.

8. The organic light-emitting diode display according to claim 4, wherein the anti-reflection layer is a circular polarizer.

9. The organic light-emitting diode display according to claim 1, wherein the organic light-emitting diode display further comprises a barrier layer positioned between the organic light-emitting diode array substrate and the protective cover.

10. The organic light-emitting diode display according to claim 9, wherein the barrier layer is an inorganic layer, or a laminated layer including a plurality of inorganic layers and a plurality of organic layers alternately stacked on the organic light-emitting diode array substrate.

11. A method of manufacturing an organic light-emitting diode display, comprising:
preparing an organic light-emitting diode array substrate, a protective cover and a sealant;
attaching the protective cover on the organic light-emitting diode array substrate; and
spreading the sealant around a periphery of the organic light-emitting diode array substrate and bonding the protective cover with the sealant.

12. The method of manufacturing an organic light-emitting diode display according to claim 11, wherein the method further comprises forming a transmission enhanced layer between the organic light-emitting diode array substrate and the protective cover.

13. The method of manufacturing an organic light-emitting diode display according to claim 12, wherein the transmission enhanced layer comprises at least two transmission enhanced layers having different refractive indexes, and a refractive index of a cathode of the organic light-emitting diode array substrate, the refractive indexes of the at least two transmission enhanced layers and a refractive index of the protective cover gradually increase or decrease in the direction from the organic light-emitting diode array substrate to the protective cover.

14. The method of manufacturing an organic light-emitting diode display according to claim 11, wherein the method further comprises attaching an anti-reflection layer.

15. The method of manufacturing an organic light-emitting diode display according to claim 14, wherein the step of attaching an anti-reflection layer comprises attaching an anti-reflection layer between the organic light-emitting diode array substrate and the protective cover.

16. The method of manufacturing an organic light-emitting diode display according to claim 15, wherein the method further comprises forming a first transmission enhanced layer positioned between the organic light-emitting diode array substrate and the anti-reflection layer, and forming a second transmission enhanced layer between the anti-reflection layer and the protective cover, wherein a refractive index of the first transmission enhanced layer falls in between a refractive index of a cathode of the organic light-emitting diode array substrate and a refractive index of the anti-reflection layer, and a refractive index of the second transmission enhanced layer falls in between the refractive index of the anti-reflection layer and a refractive index of the protective cover.

17. The method of manufacturing an organic light-emitting diode display according to claim 14, wherein the step of attaching an anti-reflection layer comprises attaching an anti-reflection layer on an outer side of the protective cover, and the outer side of the protective cover is far away from the organic light-emitting diode array substrate.

18. The method of manufacturing an organic light-emitting diode display according to claim 14, wherein the anti-reflection layer is a circular polarizer.

19. The method of manufacturing an organic light-emitting diode display according to claim 11, wherein the method further comprises forming a barrier layer between the organic light-emitting diode array substrate and the protective cover.

20. The method of manufacturing an organic light-emitting diode display according to claim 19, wherein the barrier layer is an inorganic layer, or a laminated layer including a plurality of inorganic layers and a plurality of organic layers alternately stacked on the organic light-emitting diode array substrate.
